(19) United States
(12) Patent Application Publication
(10) Pub. No.: US 2026/0128091 A1
(43) Pub. Date: May 7, 2026

(54) STATIC RANDOM ACCESS MEMORY BIT-CELL WITH COMPACT SIZE THAT SUPPORTS BIT-WRITE-MASK FEATURE AND HALF-SELECTION-FREE FEATURE

(71) Applicant: MEDIATEK INC., Hsinchu City (TW)

(72) Inventors: Tzu-Hsien Yang, Hsinchu City (TW); Yi-Te Chiu, Hsinchu City (TW)

(73) Assignee: MEDIATEK INC., Hsinchu City (TW)

(21) Appl. No.: 19/375,190

(22) Filed: Oct. 30, 2025

Related U.S. Application Data
(60) Provisional application No. 63/714,868, filed on Nov. 1, 2024.

(51) Int. Cl. G11C 11/419; G11C 5/14; G11C 11/418

(52) U.S. Cl. CPC G11C 11/419; G11C 5/147; G11C 11/418

(57) ABSTRACT

A static random access memory (SRAM) bit-cell includes a cross-coupled latch circuit, a write driver circuit, a first transistor circuit, and a second transistor circuit. The cross-coupled latch circuit includes a first transistor, a second transistor, a third transistor, and a fourth transistor. The first and second transistors form a first inverter. The third and fourth transistors form a second inverter. The first inverter and the second inverter are cross-coupled. The write driver circuit is coupled to one reference voltage and a write bit line pair, and configured to write a data input into the cross-coupled latch circuit. The first transistor circuit is coupled to connection terminals of the first transistor and the third transistor. The second transistor circuit is coupled between the write driver circuit and another reference voltage, wherein both of the first transistor circuit and the second transistor are controlled by a word line.

### CROSS REFERENCE TO RELATED APPLICATIONS

This application claims the benefit of U.S. Provisional Application No. 63/714,868, filed on Nov. 1, 2024. The content of the application is incorporated herein by reference.

### BACKGROUND

The present invention relates to a static random access memory (SRAM) design, and more particularly, to an SRAM bit-cell with a compact size that supports a bit-write-mask feature and a half-selection-free feature.

The digital two-port SRAM is designed for ultra-low voltage operation and is suitable for small to medium array sizes, offering a more compact solution compared to traditional 6T-based SRAMs. It ensures a contention-free write operation by breaking a feedback loop between a cross-coupled latch (which consists of cross-coupled inverters) during data writing. Additionally, a read buffer is employed for data reading to eliminate any disturbances on bit-cell storage nodes, enabling ultra-low voltage operation. Despite its advantages, digital two-port SRAM faces the challenge of the half-selection issue, requiring a read-modify-write operation for a 12T SRAM bit-cell, which impacts performance. Thus, there is a need for an innovative SRAM bit-cell design which can address the half-selection issue and support the bit-write mask feature, without compromising the bit-density.

### SUMMARY

One of the objectives of the claimed invention is to provide an SRAM bit-cell with a compact size that supports a bit-write-mask feature and a half-selection-free feature.

According to a first aspect of the present invention, an exemplary SRAM bit-cell is disclosed. The exemplary SRAM bit-cell includes a cross-coupled latch circuit, a write driver circuit, a first transistor circuit, and a second transistor circuit. The cross-coupled latch circuit includes a first transistor, a second transistor, a third transistor, and a fourth transistor. The first transistor has a control terminal, a first connection terminal, and a second connection terminal. The second transistor has a control terminal coupled to the control terminal of the first transistor, a first connection coupled to the first terminal of the first transistor, and a second terminal coupled to a first reference voltage. The third transistor has a control terminal coupled to the first terminal of the first transistor, a first connection terminal coupled to the control terminal of the first transistor, and a second connection terminal. The fourth transistor has a control terminal coupled to the control terminal of the third transistor, a first connection terminal coupled to the first connection terminal of the third transistor, and a second connection terminal coupled to the first reference voltage. The write driver circuit is coupled to a second reference voltage and a write bit line pair, and configured to write a data input into the cross-coupled latch circuit. The first transistor circuit is coupled to the second connection terminal of the first transistor and the second connection terminal of the third transistor. The second transistor circuit is coupled between the write driver circuit and the first reference voltage. Both of the first transistor circuit and the second transistor are controlled by a first word line.

According to a second aspect of the present invention, an exemplary 12T two-port SRAM bit-cell is disclosed. The exemplary 12T two-port SRAM bit-cell includes a first transistor, a second transistor, a third transistor, a fourth transistor, a fifth transistor, a sixth transistor, a seventh transistor, an eighth transistor, a ninth transistor, a tenth transistor, an eleventh transistor, and a twelfth transistor. The first transistor has a control terminal, a first connection terminal, and a second connection terminal. The second transistor has a control terminal coupled to the control terminal of the first transistor, a first connection coupled to the first terminal of the first transistor, and a second terminal coupled to a first reference voltage. The third transistor has a control terminal coupled to the first terminal of the first transistor, a first connection terminal coupled to the control terminal of the first transistor, and a second connection terminal. The fourth transistor has a control terminal coupled to the control terminal of the third transistor, a first connection terminal coupled to the first connection terminal of the third transistor, and a second connection terminal coupled to the first reference voltage. The fifth transistor has a control terminal coupled to a first write bit line of a write bit line pair, a first connection terminal coupled to the second connection terminal of the first transistor, and a second connection terminal coupled to a second reference voltage. The sixth transistor has a control terminal coupled to the first write bit line, a first connection terminal coupled to the first connection terminal of the first transistor, and a second connection terminal. The seventh transistor has a control terminal coupled to a second write bit line of the write bit line pair, a first connection terminal coupled to the second connection terminal of the third transistor, and a second connection terminal coupled to the second reference voltage. The eighth transistor has a control terminal coupled to the second write bit line, a first connection terminal coupled to the first connection terminal of the third transistor, and a second connection terminal. The ninth transistor has a control terminal coupled to a write word line, and two connection terminals coupled to the second connection terminal of the first transistor and the second connection terminal of the third transistor, respectively. The tenth transistor has a control terminal coupled to the write word line, a first connection terminal coupled to the second connection terminal of the sixth transistor and the second connection terminal of the eighth transistor, and a second connection terminal coupled to the first reference voltage. The eleventh transistor has a control terminal coupled to the first connection terminal of the third transistor, a first connection terminal, and a second connection terminal coupled to one of the first reference voltage and the second reference voltage. The twelfth transistor has a control terminal coupled to a read word line, a first connection terminal coupled to a read bit line, and a second connection terminal coupled to the first connection terminal of the eleventh transistor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a first SRAM bit-cell that supports a bit-write-mask feature and a half-selection-free feature according to an embodiment of the present invention.

FIG. 2 is a diagram illustrating operations of different SRAM bit-cells in a memory array according to an embodiment of the present invention.

FIG. 3 is a diagram illustrating operations of different SRAM bit-cells in a memory array according to an embodiment of the present invention.

FIG. 4 is a diagram illustrating a front-end-of-line (FEOL) layout of the SRAM bit-cell 100 according to an embodiment of the present invention.

FIG. 5 is a diagram illustrating a first part of bit-cell back-end routing according to an embodiment of the present invention.

FIG. 6 is a diagram illustrating a second part of bit-cell back-end routing according to an embodiment of the present invention.

FIG. 7 is a diagram illustrating a first alternative design of a read buffer circuit according to an embodiment of the present invention.

FIG. 8 is a diagram illustrating a second alternative design of a read buffer circuit according to an embodiment of the present invention.

FIG. 9 is a diagram illustrating a third alternative design of a read buffer circuit according to an embodiment of the present invention.

FIG. 10 is a diagram illustrating a fourth alternative design of a read buffer circuit according to an embodiment of the present invention.

FIG. 11 is a diagram illustrating a second SRAM bit-cell that supports a bit-write-mask feature and a half-selection-free feature according to an embodiment of the present invention.

FIG. 12 is a diagram illustrating a third SRAM bit-cell that supports a bit-write-mask feature and a half-selection-free feature according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

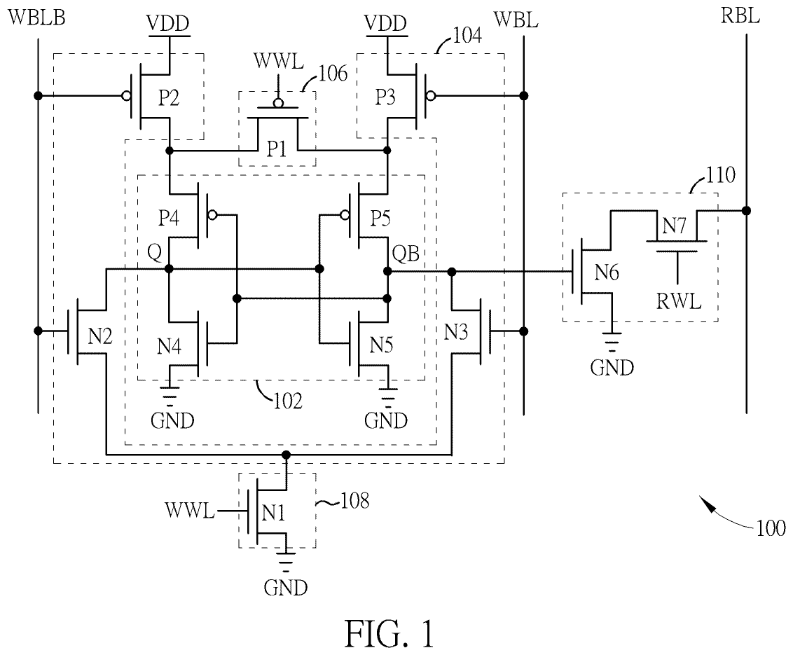

FIG. 1 is a diagram illustrating a first SRAM bit-cell that supports a bit-write-mask feature and a half-selection-free feature according to an embodiment of the present invention. The SRAM bit-cell 100 is a 12-transistor (12T) digital two-port SRAM bit-cell with a compact size, and includes a cross-coupled latch circuit 102, a write driver circuit 104, a plurality of transistor circuits 106, 108, and a read buffer circuit 110. The cross-coupled latch circuit 102 is used to store one bit, and includes a plurality of transistors P4, P5, N4, N5, where the transistors P4 and P5 are P-channel metal-oxide-semiconductor (PMOS) transistors, and the transistors N4 and N5 are N-channel metal-oxide-semiconductor (NMOS) transistors. The transistors P4 and N4 are used to form a first inverter. The transistors P5 and N5 are used to form a second inverter. In addition, the first inverter and the second inverter are crossed-coupled. Specifically, the transistor P4 has a gate terminal coupled to a bit-cell storage node QB, a drain terminal coupled to a bit-cell storage node Q, and a source terminal; the transistor N4 has a gate terminal coupled to the bit-cell storage node QB, a drain terminal coupled to the bit-cell storage node Q, and a source terminal coupled to a first reference voltage (e.g., ground voltage GND); the transistor P5 has a gate terminal coupled to the bit-cell storage node Q, a drain terminal coupled to the bit-cell storage node QB, and a source terminal; and the transistor N5 has a gate terminal coupled to the bit-cell storage node Q, a drain terminal coupled to the bit-cell storage node QB, and a source terminal coupled to the first reference voltage (e.g., ground voltage GND). When the bit-cell storage node Q stores a bit value 1, the bit-cell storage node QB stores a bit value 0, and vice versa.

The write driver circuit 104 is capable of breaking a feedback loop of the cross-coupled latch circuit 102 during a write operation of a selected SRAM bit-cell, and includes a plurality of transistors P2, P3, N2, N3, where the transistors P2 and P3 are PMOS transistors, and the transistors N2 and N3 are NMOS transistors. Specifically, the transistor P2 has a gate terminal coupled to a write bit line WBLB, a drain terminal coupled to the source terminal of the transistor P4, and a source terminal coupled to a second reference voltage (e.g., supply voltage VDD that is higher than the ground voltage GND); the transistor N2 has a gate terminal coupled to the write bit line WBLB, a drain terminal coupled to the bit-cell storage node Q, and a source terminal; the transistor P3 has a gate terminal coupled to a write bit line WBL, a drain terminal coupled to the source terminal of the transistor P5, and a source terminal coupled to the second reference voltage (e.g., supply voltage VDD); and the transistor N3 has a gate terminal coupled to the write bit line WBL, a drain terminal coupled to the bit-cell storage node QB, and a source terminal. The write bit lines WBL and WBLB form a write bit line pair. During a write operation of a selected SRAM bit-cell, write bit lines WBL and WBLB of the same write bit line pair that is connected to the selected SRAM bit-cell are used to act as a complementary write bit line pair.

The transistor circuits 106 and 108 are used to achieve the half-selection-free feature. In this embodiment, the transistor circuit 106 may be implemented using a single transistor P1, and the transistor circuit 108 may be implemented using a single transistor N1, where the transistor P1 is a PMOS transistor, and the transistor N1 is an NMOS transistor. Specifically, the transistor P1 acts as an equalizer, and the transistor N1 acts as a global footer transistor. A gate terminal of the transistor P1 is coupled to a write word line WWL, and two connection nodes of the transistor P1 are coupled to source terminals of transistors P4 and P5, respectively. The transistor N1 has a gate terminal coupled to the write word line WWL, a drain terminal coupled to source terminals of transistors N2 and N3, and a source terminal coupled to the first reference voltage (e.g., ground voltage GND).

The read buffer circuit 110 is used to perform a disturbance-free read operation for reading one bit stored in the SRAM bit-cell 100, and includes a plurality of transistors N6 and N7, where the transistors N6 and N7 are NMOS transistors. Specifically, the transistor N6 has a gate terminal coupled to the bit-cell storage node QB, a drain terminal, and a source terminal coupled to the first reference voltage (e.g., ground voltage GND); and the transistor N7 has a gate terminal coupled to a read word line RWL, a drain terminal coupled to a read bit line RBL, and a source terminal coupled to the drain terminal of the transistor N6.

A read operation of a bit stored in the SRAM bit-cell 100 is performed through two global signals including the read word line RWL and the read bit line RBL. The read word line RWL determines whether the SRAM bit-cell 100 is selected. If the SRAM bit-cell 100 is selected, the bit stored in the SRAM bit-cell 100 is read out through the read bit line RBL. Different conditions of the read operation are listed in the following table.

TABLE 1

| Read | RWL | RBL |
|---|---|---|
| Selected | 1 | Read Q |
| Unselected | 0 | No Read |

A write operation of a bit in the SRAM bit-cell 100 is performed through three global signals including the write word line WWL and the write bit lines WBL and WBLB. The write word line WWL determines whether the SRAM bit-cell 100 is selected. If the SRAM bit-cell 100 is selected, a data input DI is written into the SRAM bit-cell 100 through the write bit lines WBL and WBLB, where Q=DI and QB=DIB. Different conditions of the write operation are listed in the following table.

TABLE 2

| Write | WWL | WBL | WBLB | Q |
|---|---|---|---|---|
| Sel-WL, Sel-BL | 1 | DI | DIB | Write DI |
| Sel-WL, Unsel-BL | 1 | 0 | 0 | Keep |
| Unsel-WL, Sel-BL | 0 | DI | DIB | Keep |
| Unsel-WL, Unsel-BL | 0 | 0 | 0 | Keep |

When the SRAM bit-cell 100 operates in a standby mode, the read word line RWL, the read bit line RBL, the write word line WWL, and the write bit lines WBL, WBLB are set by O's. When the write word line WWL is toggled (WWL=1), the SRAM bit-cell 100 is selected for data writing (WBL=DI & WBLB=DIB). When the read word line RWL is toggled (RWL=1), the SRAM bit-cell 100 is selected for data reading (RBL=Q).

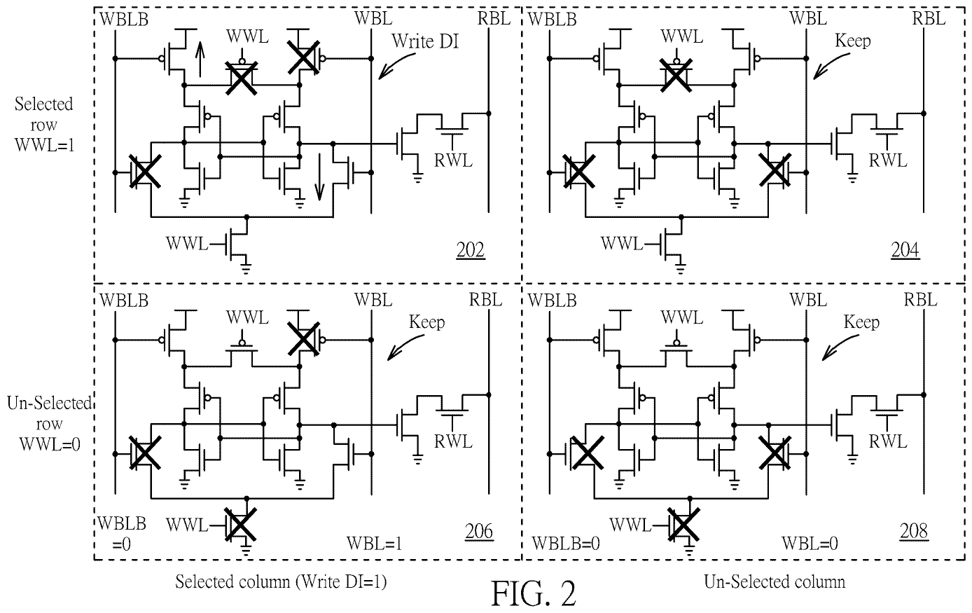

The SRAM bit-cell 100 supports a half-selection-free feature. That is, the SRAM bit-cell 100 has no half-selection issue. FIG. 2 is a diagram illustrating operations of different SRAM bit-cells in a memory array according to an embodiment of the present invention. Each of the SRAM bit-cells 202, 204, 206, 208 may be implemented using the proposed SRAM bit-cell design shown in FIG. 1. The SRAM bit-cells 202 and 204 belong to a same SRAM bit-cell row but different SRAM bit-cell columns. The SRAM bit-cells 206 and 208 belong to a same SRAM bit-cell row but different SRAM bit-cell columns. The SRAM bit-cells 202 and 206 belong to a same SRAM bit-cell column but different SRAM bit-cell rows. The SRAM bit-cells 204 and 208 belong to a same SRAM bit-cell column but different SRAM bit-cell rows. In this embodiment, the SRAM bit-cell 202 is a selected SRAM bit-cell located at a selected row (WWL=1) and a selected column (WBL=1 & WBLB=0), the SRAM bit-cell 204 is a half-selected SRAM bit-cell located at a selected row (WWL=1) and an unselected column (WBL=WBLB=0), the SRAM bit-cell 206 is a half-selected located at an unselected row (WWL=0) and a selected column (WBL=1 & WBLB=0), and the SRAM bit-cell 208 is an unselected SRAM bit-cell located at an unselected row (WWL=0) and an unselected column (WBL=WBLB=0).

Suppose that DI=1 is requested to be written into the selected SRAM bit-cell 202. Regarding the SRAM bit-cell 202 implemented using the SRAM bit-cell 100 shown in FIG. 1, the transistor P1 is turned off by WWL=1, the transistor N1 is turned on by WWL=1, the transistor P2 is turned on by WBLB=DIB=0, the transistor N2 is turned off by WBLB=DIB=0, the transistor P3 is turned off by WBL=DI=1, and the transistor N3 is turned on by WBL=DI=1. Considering a case where Q=0 and QB=1 are originally stored by the SRAM bit-cell 202, the data input DI=1 can be easily written into the SRAM bit-cell 202 with the aid of breaking the path between the bit-cell storage node QB and the second reference voltage (e.g., supply voltage VDD). The voltage level at the bit-cell storage node QB is pulled down through the turned-on transistors N3 and N1. After the transistor N4 is turned off by QB and the transistor NP is turned on by QB, the voltage level at the bit-cell storage node Q is pulled up through the turned-on transistors P4 and P2, and turns on the transistor N5.

Regarding the SRAM bit-cell 204 implemented using the SRAM bit-cell 100 shown in FIG. 1, the transistor P1 is turned off by WWL=1, the transistor N1 is turned on by WWL=1, the transistor P2 is turned on by WBLB=0, the transistor N2 is turned off by WBLB=0, the transistor P3 is turned on by WBL=0, and the transistor N3 is turned off by WBL=0. Since the transistors N2 and N3 are both turned off, the bit-cell storage nodes Q and QB are not affected by the first reference voltage (e.g., ground voltage GND) coupled to the source terminal of the turned-on transistor N1. Since the transistors P2 and P3 are both turned on for providing the second reference voltage (e.g., supply voltage VDD) to source terminals of the transistors P4 and P5 included in the cross-coupled latch circuit 102, the cross-coupled latch circuit 102 operates normally to keep the stored bit of the SRAM bit-cell 204 unchanged. In this way, the stored bit of the SRAM bit-cell 204 is free of the half selection (i.e., WWL=1 & WBL=WBLB=0) of the SRAM bit-cell 204.

Regarding the SRAM bit-cell 206 implemented using the SRAM bit-cell 100 shown in FIG. 1, the transistor P1 is turned on by WWL=0, the transistor N1 is turned off by WWL=0, the transistor P2 is turned on by WBLB=0, the transistor N2 is turned off by WBLB=0, the transistor P3 is turned off by WBL=DI=1, and the transistor N3 is turned on by WBL=DI=1. Although the transistor N3 is turned on, the transistor N1 is turned off for disconnecting the bit-cell storage node QB from the first reference voltage (e.g., ground voltage GND). In addition, since the transistors N1 and N2 are turned off, the bit-cell storage node Q is not affected by the first reference voltage (e.g., ground voltage GND) coupled to the source terminal of the transistor N1. The transistor P1 is turned on for providing the second reference voltage (e.g., supply voltage VDD) to the source terminal of the transistor P4 included in the cross-coupled latch circuit 102. Although the transistor P3 is turned off, the transistors P1 and P2 are both turned on for providing the second reference voltage (e.g., supply voltage VDD) to the source terminal of the transistor P5 included in the cross-coupled latch circuit 102. Hence, the cross-coupled latch circuit 102 operates normally to keep the stored bit of the SRAM bit-cell 204 unchanged. In this way, the stored bit of the SRAM bit-cell 204 is free of the half selection (i.e., WWL=0 & WBL=DI/WBLB=DIB) of the SRAM bit-cell 206.

Regarding the SRAM bit-cell 208 implemented using the SRAM bit-cell 100 shown in FIG. 1, the transistor P1 is turned on by WWL=0, the transistor N1 is turned off by WWL=0, the transistor P2 is turned on by WBLB=0, the transistor N2 is turned off by WBLB=0, the transistor P3 is turned on by WBL=0, and the transistor N3 is turned off by WBL=0. Since the transistors N1, N2, N3 are all turned off, none of the bit-cell storage nodes Q and QB is affected by the second reference voltage (e.g., ground voltage GND) coupled to the source terminal of the transistor N1. The transistors P2 and P3 are both turned on for providing the second reference voltage (e.g., supply voltage VDD) to source terminals of the transistors P4 and P5 included in the cross-coupled latch circuit 102. The cross-coupled latch circuit 102 operates normally to keep the stored bit of the SRAM bit-cell 204 unchanged.

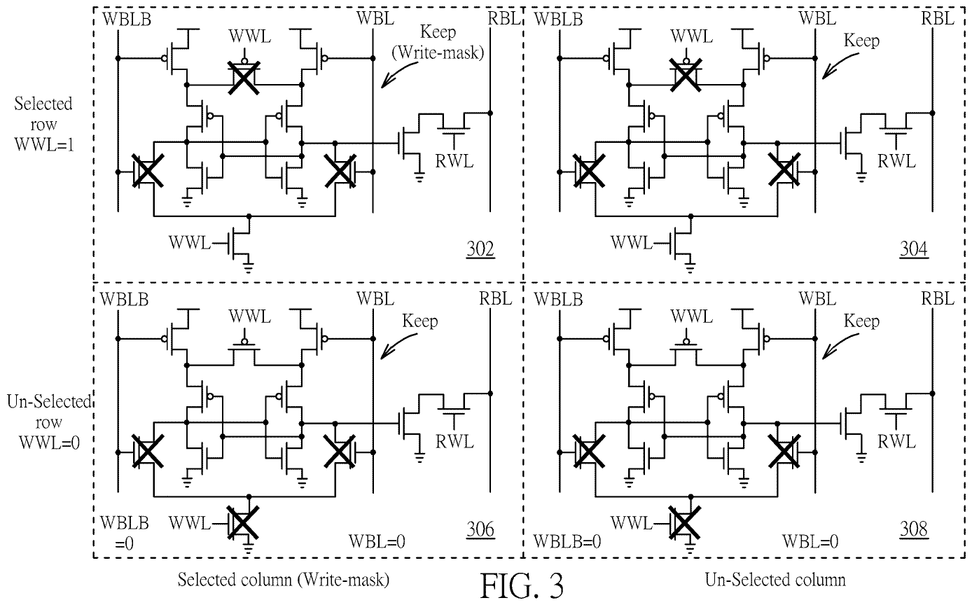

In addition to the half-selection-free feature, the SRAM bit-cell 100 further supports a bit-write-mask feature. FIG. 3 is a diagram illustrating operations of different SRAM bit-cells in a memory array according to an embodiment of the present invention. Each of the SRAM bit-cells 302, 304, 306, 308 may be implemented using the proposed SRAM bit-cell design shown in FIG. 1. The SRAM bit-cells 302 and 304 belong to a same SRAM bit-cell row but different SRAM bit-cell columns. The SRAM bit-cells 306 and 308 belong to a same SRAM bit-cell row but different SRAM bit-cell columns. The SRAM bit-cells 302 and 306 belong to a same SRAM bit-cell column but different SRAM bit-cell rows. The SRAM bit-cells 304 and 308 belong to a same SRAM bit-cell column but different SRAM bit-cell rows. In this embodiment, the SRAM bit-cell 302 is a selected SRAM bit-cell, and a bit-write-mask function of the selected SRAM bit-cell is enabled for masking a write operation of the selected SRAM bit-cell. For example, the bit-write-mask function of the selected SRAM bit-cell is enabled by setting the selected write bit lines WBL and WBLB to WBL=WBLB=0.

As shown in FIG. 3, the SRAM bit-cell 302 is located at a selected row (WWL=1) and a selected column (WBL=WBLB=0 due to bit-write-mask), the SRAM bit-cell 304 is a half-selected SRAM bit-cell located at a selected row (WWL=1) and an unselected column (WBL=WBLB=0), the SRAM bit-cell 306 is a half-selected located at an unselected row (WWL=0) and a selected column (WBL-WBLB=0 due to bit-write-mask), and the SRAM bit-cell 308 is an unselected SRAM bit-cell located at an unselected row (WWL=0) and an unselected column (WBL=WBLB=0).

Regarding the SRAM bit-cell 302 implemented using the SRAM bit-cell 100 shown in FIG. 1, the transistor P1 is turned off by WWL=1, the transistor N1 is turned on by WWL=1, the transistor P2 is turned on by WBLB=0, the transistor N2 is turned off by WBLB=0, the transistor P3 is turned on by WBL=0, and the transistor N3 is turned off by WBL=0. The SRAM bit-cell 302 is a selected SRAM bit-cell, but is bit-write-masked due to the bit-write-mask function enabled at the selected SRAM bit-cell. Since the transistors N2 and N3 are turned off, the bit-cell storage nodes Q and QB are not affected by the first reference voltage (e.g., ground voltage GND) coupled to the source terminal of the turned-on transistor N1. Since the transistors P2 and P3 are both turned on for providing the second reference voltage (e.g., supply voltage VDD) to source terminals of the transistors P4 and P5 included in the cross-coupled latch circuit 102, the cross-coupled latch circuit 102 operates normally to keep the stored bit of the bit-write-masked SRAM bit-cell 302 unchanged. Since the operation of the SRAM bit-cell 304 is the same as that of the SRAM bit-cell 302, the same description is omitted here for brevity.

Regarding the SRAM bit-cell 306 implemented using the SRAM bit-cell 100 shown in FIG. 1, the transistor P1 is turned on by WWL=0, the transistor N1 is turned off by WWL=0, the transistor P2 is turned on by WBLB=0, the transistor N2 is turned off by WBLB=0, the transistor P3 is turned on by WBL=0, and the transistor N3 is turned off by WBL=0. Since the transistors N1, N2, N3 are all turned off, none of the bit-cell storage nodes Q and QB is affected by the first reference voltage (e.g., ground voltage GND) coupled to the source terminal of the transistor N1. The transistors P2 and P3 are both turned on for providing the second reference voltage (e.g., supply voltage VDD) to source terminals of the transistors P4 and P5 included in the cross-coupled latch circuit 102. The cross-coupled latch circuit 102 operates normally to keep the stored bit of the SRAM bit-cell 306 unchanged. Since the operation of the SRAM bit-cell 308 is the same as that of the SRAM bit-cell 306, the same description is omitted here for brevity.

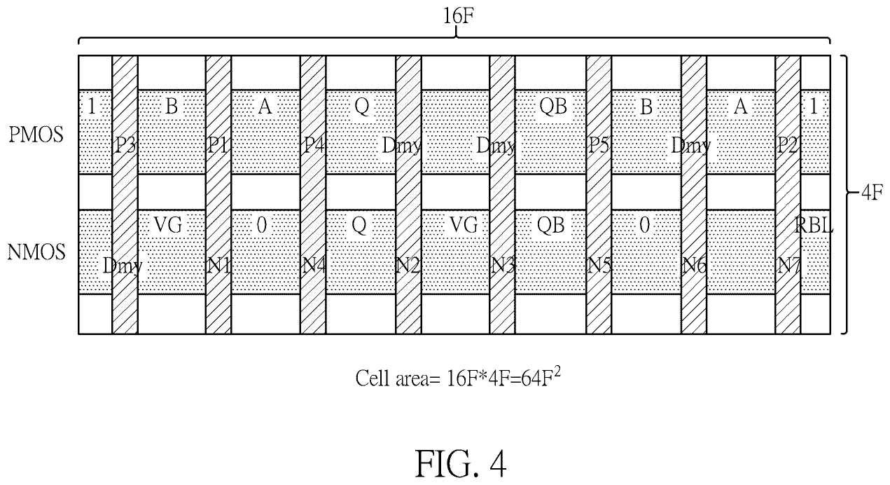

With a proper layout design of the SRAM bit-cell 100 shown in FIG. 1, a die area occupied by the SRAM bit-cell 100 can be minimized. FIG. 4 is a diagram illustrating a front-end-of-line (FEOL) layout of the SRAM bit-cell 100 according to an embodiment of the present invention. The FEOL layout defines an arrangement of transistors included in the SRAM bit-cell 100. Poly gates and active areas (which are defined by the oxide diffusion (OD) layer) are illustrated in FIG. 4. In accordance with the proposed FEOL layout shown in FIG. 4, five transistors (PMOS transistors) P3, P1, P4, P5, P2 and three dummy transistors (PMOS transistors) Dmy are at a first row; seven transistors (NMOS transistors) N1, N4, N2, N3, N5, N6, N7 and one dummy transistor (NMOS transistor) Dmy are at a second row adjacent to the first row; the transistor P3 and one dummy transistor (NMOS transistor) Dmy are at a first column; the transistors P1 and N1 at a second column between the first column and a third column; the transistors P4 and N4 are at the third column between the second column and a fourth column; one dummy transistor (PMOS transistor) Dmy are at the fourth column between the third column and a fifth column; one dummy transistor (PMOS transistor) Dmy and the transistor N3 are at the fifth column between the fourth column and a sixth column; the transistors P5 and N5 are at the sixth column between the fifth column and a seventh column; and one dummy transistor (PMOS transistor) Dmy and the transistor N6 are at the seventh column between the sixth column and an eighth column; and the transistors P2 and N7 are at the eighth column. The proposed FEOL layout has an X-direction size being 16F and a Y-direction size being 4F, where F is a feature size determined by a semiconductor process. Hence, a cell area of the proposed SRAM bit-cell 100 (which is a 12T SRAM bit-cell with a self-selection-free feature and a bit-write-mask feature) is 64F² that is the same as that of a conventional 12T SRAM bit-cell without a self-selection-free feature and a bit-write-mask feature, and is smaller than a cell area (e.g., 80F²) of a conventional 16T SRAM bit-cell with a self-selection-free feature and a bit-write-mask feature. Specifically, the proposed SRAM bit-cell 100 requires 12 transistors and 5 global signals, thus achieving higher bit-density and less global routing compared to the conventional 16T SRAM bit-cell.

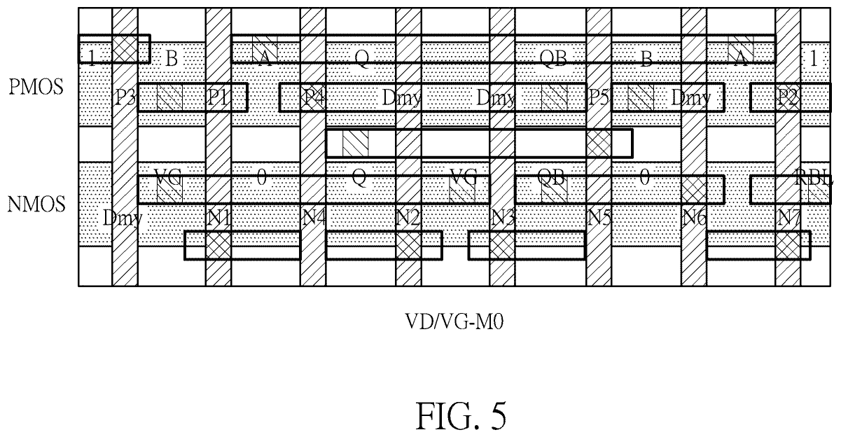

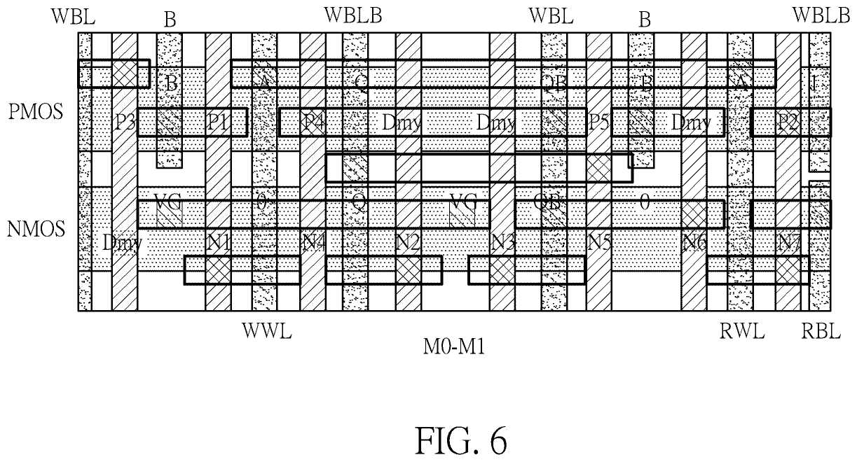

By way of example, but not limitation, a semiconductor process for fabricating the proposed SRAM bit-cell 100 may be divided into an FEOL process and a back-end-of-line (BEOL) process. Hence, the transistors fabricated by the FEOL process are interconnected through routing fabricated in the BEOL process. FIG. 5 and FIG. 6 are diagrams illustrating different parts of bit-cell back-end routing according to an embodiment of the present invention. Specifically, vias formed by the VD layer, vias formed by the VG layer, and routing traces formed by the metal layer M0 are illustrated in FIG. 5, and additional routing traces formed on the metal layer M1 are illustrated in FIG. 6.

The read buffer circuit 110 is used to perform a disturbance-free read operation for reading one bit stored in the SRAM bit-cell 100. The circuit design of the read buffer circuit 110 shown in FIG. 1 is for illustrative purposes only, and is not meant to be a limitation of the present invention. In practice, any means capable of performing a disturbance-free read operation may be adopted.

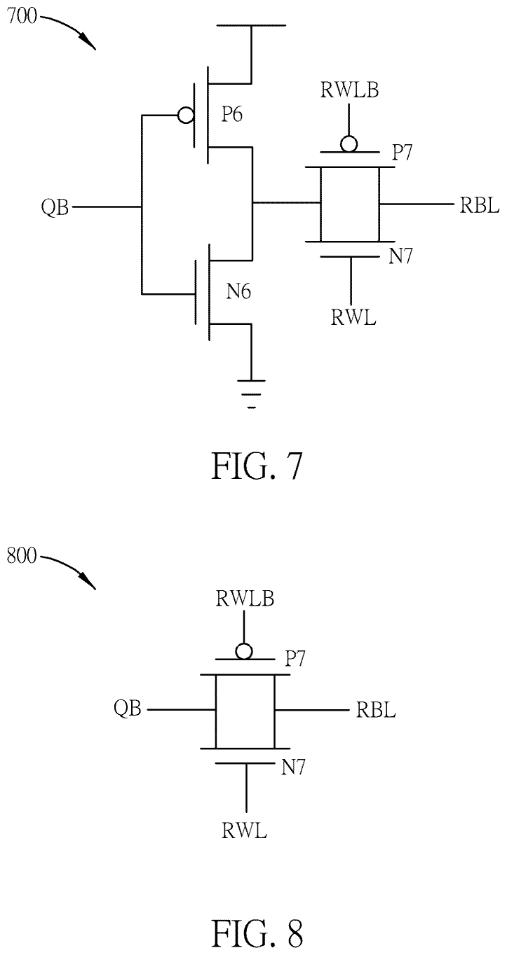

FIG. 7 is a diagram illustrating a first alternative design of a read buffer circuit according to an embodiment of the present invention. The SRAM bit-cell 100 may be modified to have the read buffer circuit 110 replaced by the read buffer circuit 700. The read buffer circuit 700 is a complementary metal-oxide-semiconductor (CMOS) circuit including transistors P6, P7, N6, N7, where transistors P6 and P7 are PMOS transistors, and transistors N6 and N7 are NMOS transistors. The transistor P6 and N6 form an inverter. The transistors P7 and N7 form a pass gate controlled by a complementary read word line pair (RWL, RWLB).

FIG. 8 is a diagram illustrating a second alternative design of a read buffer circuit according to an embodiment of the present invention. The SRAM bit-cell 100 may be modified to have the read buffer circuit 110 replaced by the read buffer circuit 800. The read buffer circuit 800 is a pass gate including transistors P7 and N7 controlled by a complementary read word line pair (RWL, RWLB), where the transistor P7 is a PMOS transistor, and the transistor N7 is an NMOS transistor.

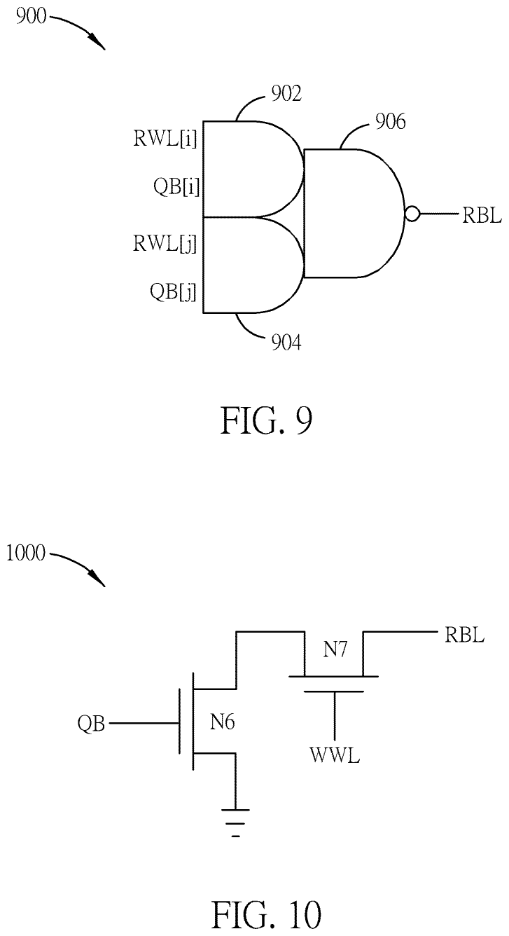

FIG. 9 is a diagram illustrating a third alternative design of a read buffer circuit according to an embodiment of the present invention. The SRAM bit-cell 100 may be modified to have the read buffer circuit 110 replaced by the read buffer circuit 900. The read buffer circuit 900 is a combinational logic. For example, the combinational logic may include two AND gates 902, 904 and one NAND gate 906.

The SRAM bit-cell 100 is a two-port SRAM bit-cell with a read port and a write port controlled by separate word lines WWL and RWL. In some embodiments of the present invention, the half-selection-free feature may also be implemented in a single-port SRAM bit-cell with a read operation and a write operation controlled by a same word line. FIG. 10 is a diagram illustrating a fourth alternative design of a read buffer circuit according to an embodiment of the present invention. The major difference between the read buffer circuits 110 and 1000 is that the gate terminal of the transistor N7 of the read buffer circuit 100n is also coupled to the write word line WWL. In other words, the write word line WWL and the read word line RWL are merged into a single word line, thereby converting the two-port SRAM bit-cell 100 into a single-port SRAM bit-cell.

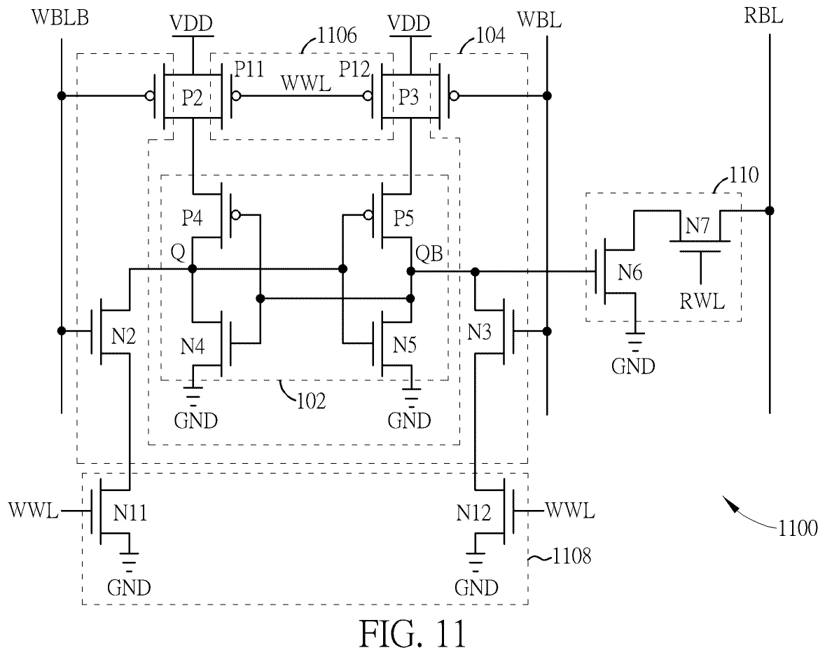

In the embodiment shown in FIG. 1, the transistor circuit 106 is implemented using a single transistor P1, and the transistor circuit 108 is implemented using a single transistor N1. However, this is for illustrative purposes only, and is not meant to be a limitation of the present invention. FIG. 11 is a diagram illustrating a second SRAM bit-cell that supports a bit-write-mask feature and a half-selection-free feature according to an embodiment of the present invention. The SRAM bit-cell 1100 is a 12T digital two-port SRAM bit-cell with a compact size, and includes transistor circuits 1106, 1108 and the aforementioned cross-coupled latch circuit 102, write driver circuit 104, and read buffer circuit 110. In this embodiment, the transistor circuit 1106 is implemented using a plurality of transistors P11 and P12, where the transistors P11 and P12 are PMOS transistors. Specifically, the transistor P11 has a gate terminal coupled to the write word line WWL, a drain terminal coupled to the source terminal of the transistor P4, and a source terminal coupled to the second reference voltage (e.g., supply voltage VDD), and the transistor P12 has a gate terminal coupled to the write word line WWL, a drain terminal coupled to the source terminal of the transistor P5, and a source terminal coupled to the second reference voltage (e.g., supply voltage VDD). The transistors P11 and P12 act as pull-high devices when turned on by WWL=0.

In addition, the transistor circuit 1108 includes a plurality of transistors N11 and N12, where the transistors N11 and N12 are NMOS transistors. Specifically, the transistor N11 has a gate terminal coupled to the write word line WWL, a drain terminal coupled to the source terminal of the transistor N2, and a source terminal coupled to the first reference voltage (e.g., ground voltage GND), and the transistor N12 has a gate terminal coupled to the write word line WWL, a drain terminal coupled to the source terminal of the transistor N3, and a source terminal coupled to the first reference voltage (e.g., ground voltage GND). The transistors N11 and N12 act as stacking footer transistors when turned on by WWL=1.

The SRAM bit-cell 1100 may be created through replacing the transistor circuit 106 of the SRAM bit-cell 100 with the transistor circuit 1106 and replacing the transistor circuit 108 of the SRAM bit-cell 100 with the transistor circuit 1108. However, this is for illustrative purposes only, and is not meant to be a limitation of the present invention. In practice, any SRAM bit-cell using one or both of the transistor circuits 1106 and 1108 falls within the scope of the present invention.

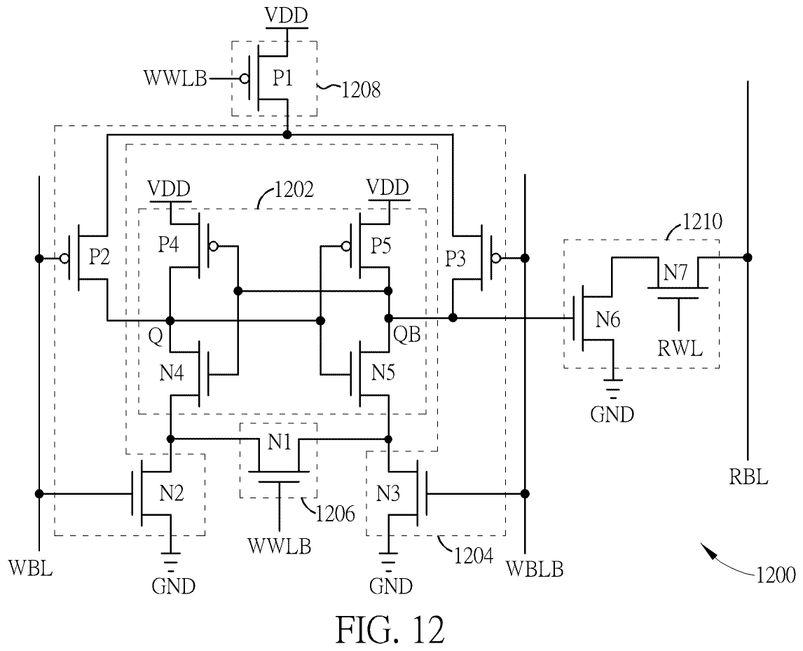

Regarding the SRAM bit-cell 100 shown in FIG. 1, it includes P-type devices and N-type devices. It should be noted that the same functionality can be achieved by swapping P-type devices and N-type devices and signal polarities of global signals. FIG. 12 is a diagram illustrating a third SRAM bit-cell that supports a bit-write-mask feature and a half-selection-free feature according to an embodiment of the present invention. The SRAM bit-cell 1200 is a 12T digital two-port SRAM bit-cell with a compact size, and includes a cross-coupled latch circuit 1202, a write driver circuit 1204, a plurality of transistor circuits 1206, 1208, and a read buffer circuit 1210. The cross-coupled latch circuit 1202 is used to store one bit, and includes a plurality of transistors P4, P5, N4, N5, where the transistors P4 and P5 are PMOS transistors, and the transistors N4 and N5 are NMOS transistors. The transistors P4 and N4 are used to form a first inverter. The transistors P5 and N5 are used to form a second inverter. In addition, the first inverter and the second inverter are crossed-coupled. Specifically, the transistor N4 has a gate terminal coupled to a bit-cell storage node QB, a drain terminal coupled to a bit-cell storage node Q, and a source terminal; the transistor P4 has a gate terminal coupled to the bit-cell storage node QB, a drain terminal coupled to the bit-cell storage node Q, and a source terminal coupled to a first reference voltage (e.g., supply voltage VDD); the transistor N5 has a gate terminal coupled to the bit-cell storage node Q, a drain terminal coupled to the bit-cell storage node QB, and a source terminal; and the transistor P5 has a gate terminal coupled to the bit-cell storage node Q, a drain terminal coupled to the bit-cell storage node QB, and a source terminal coupled to the first reference voltage (e.g., supply voltage VDD).

The write driver circuit 1204 is capable of breaking a feedback loop of the cross-coupled latch circuit 1202 during a write operation of a selected SRAM bit-cell. The write driver circuit 1204 includes a plurality of transistors P2, P3, N2, N3, where the transistors P2 and P3 are PMOS transistors, and the transistors N2 and N3 are NMOS transistors. Specifically, the transistor N2 has a gate terminal coupled to a write bit line WBL, a drain terminal coupled to the source terminal of the transistor N4, and a source terminal coupled to a second reference voltage (e.g., ground voltage GND that is lower than the supply voltage VDD); the transistor P2 has a gate terminal coupled to the write bit line WBL, a drain terminal coupled to the bit-cell storage node Q, and a source terminal; the transistor N3 has a gate terminal coupled to a write bit line WBLB, a drain terminal coupled to the source terminal of the transistor N5, and a source terminal coupled to the second reference voltage (e.g., ground voltage GND); and the transistor P3 has a gate terminal coupled to the write bit line WBLB, a drain terminal coupled to the bit-cell storage node QB, and a source terminal. The write bit lines WBL and WBLB form a write bit line pair. During a write operation of a selected SRAM bit-cell, write bit lines WBL and WBLB of the same write bit line pair that is connected to the selected SRAM bit-cell are used to act as a complementary write bit line pair.

The transistor circuits 1206 and 1208 are used to achieve the half-selection-free feature. In this embodiment, the transistor circuit 1206 may be implemented using a single transistor N1, and the transistor circuit 1208 may be implemented using a single transistor P1, where the transistor P1 is a PMOS transistor, and the transistor N1 is an NMOS transistor. Specifically, the transistor N1 acts as an equalizer, and the transistor P1 acts as a global header transistor. A gate terminal of the transistor N1 is coupled to a write word line WWLB, and two connection nodes of the transistor N1 are coupled to source terminals of transistors N4 and N5, respectively. The transistor P1 has a gate terminal coupled to the write word line WWLB, a drain terminal coupled to source terminals of transistors P2 and P3, and a source terminal coupled to the first reference voltage (e.g., supply voltage VDD).

The read buffer circuit 1210 is used to perform a disturbance-free read operation for the SRAM bit-cell 1200, and includes a plurality of transistors N6 and N7, where the transistors N6 and N7 are NMOS transistors. Specifically, the transistor N6 has a gate terminal coupled to the bit-cell storage node QB, a drain terminal, and a source terminal coupled to the second reference voltage (e.g., ground voltage GND); and the transistor N7 has a gate terminal coupled to a read word line RWL, a drain terminal coupled to a read bit line RBL, and a source terminal coupled to the drain terminal of the transistor N6.

As can be seen from FIG. 1 and FIG. 12, the cross-coupled latch circuit 1202, the write driver circuit 1204, and transistor circuits 1206, 1208 may be derived from applying transistor-type swapping and global signal polarity swapping to the cross-coupled latch circuit 102, the write driver circuit 104, and transistor circuits 106, 108. Since a person skilled in the art can readily understand details of the SRAM bit-cell 1200 after reading above paragraphs directed to the SRAM bit-cell 100, similar description is omitted here for brevity.

In some embodiments of the present invention, the transistor circuit 1206 may be replaced by a transistor circuit including a plurality of NMOS transistors that act as pull-low devices when turned on by WWLB=1. The concept is similar to that illustrated in FIG. 11. Further description is omitted here for brevity.

In some embodiments of the present invention, the transistor circuit 1208 may be replaced by a transistor circuit including a plurality of PMOS transistors that act as stacking header transistors when turned on by WWLB=0. The concept is similar to that illustrated in FIG. 11. Further description is omitted here for brevity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A static random access memory (SRAM) bit-cell comprising:
a cross-coupled latch circuit, comprising:
a first transistor, having a control terminal, a first connection terminal, and a second connection terminal;
a second transistor, having a control terminal coupled to the control terminal of the first transistor, a first connection coupled to the first terminal of the first transistor, and a second terminal coupled to a first reference voltage;
a third transistor, having a control terminal coupled to the first terminal of the first transistor, a first connection terminal coupled to the control terminal of the first transistor, and a second connection terminal; and
a fourth transistor, having a control terminal coupled to the control terminal of the third transistor, a first connection terminal coupled to the first connection terminal of the third transistor, and a second connection terminal coupled to the first reference voltage;
a write driver circuit, coupled to a second reference voltage and a write bit line pair, and configured to write a data input into the cross-coupled latch circuit;
a first transistor circuit, coupled to the second connection terminal of the first transistor and the second connection terminal of the third transistor; and
a second transistor circuit, coupled between the write driver circuit and the first reference voltage, wherein both of the first transistor circuit and the second transistor are controlled by a first word line.

2. The SRAM bit-cell of claim 1, wherein the write driver circuit comprises:
a fifth transistor, having a control terminal coupled to a first write bit line of the write bit line pair, a first connection terminal coupled to the second connection terminal of the first transistor, and a second connection terminal coupled to the second reference voltage;
a sixth transistor, having a control terminal coupled to the first write bit line, a first connection terminal coupled to the first connection terminal of the first transistor, and a second connection terminal coupled to the second transistor circuit;
a seventh transistor, having a control terminal coupled to a second write bit line of the write bit line pair, a first connection terminal coupled to the second connection terminal of the third transistor, and a second connection terminal coupled to the second reference voltage; and
an eighth transistor, having a control terminal coupled to the second write bit line, a first connection terminal coupled to the first connection terminal of the third transistor, and a second connection terminal coupled to the second transistor circuit.

3. The SRAM bit-cell of claim 2, wherein the first transistor circuit comprises:
a ninth transistor, having a control terminal coupled to the first word line, and two connection terminals coupled to the second connection terminal of the first transistor and the second connection terminal of the third transistor, respectively.

4. The SRAM bit-cell of claim 2, wherein the first transistor circuit comprises:
a ninth transistor, having a control terminal coupled to the first word line, a first connection terminal coupled to the second connection terminal of the first transistor, and a second connection terminal coupled to the second reference voltage; and
a tenth transistor, having a control terminal coupled to the first word line, a first connection terminal coupled to the second connection terminal of the third transistor, and a second connection terminal coupled to the second reference voltage.

5. The SRAM bit-cell of claim 2, wherein the second transistor circuit comprises:
a ninth transistor, having a control terminal coupled to the first word line, a first connection terminal coupled to the second connection terminal of the sixth transistor and the second connection terminal of the eighth transistor, and a second connection terminal coupled to the first reference voltage.

6. The SRAM bit-cell of claim 2, wherein the second transistor circuit comprises:
a ninth transistor, having a control terminal coupled to the first word line, a first connection terminal coupled to the second connection terminal of the sixth transistor, and a second connection terminal coupled to the first reference voltage; and
a tenth transistor, having a control terminal coupled to the first word line, a first connection terminal coupled to the second connection terminal of the eighth transistor, and a second connection terminal coupled to the first reference voltage.

7. The SRAM bit-cell of claim 1, further comprising:
a read buffer circuit, coupled between the first connection terminal of the third transistor and a read bit line.

8. The SRAM bit-cell of claim 7, wherein the first word line is a write word line, and the read buffer circuit is controlled by a second word line being a read word line.

9. The SRAM bit-cell of claim 7, wherein the read buffer circuit is controlled by the first word line.

10. The SRAM bit-cell of claim 7, wherein the read buffer circuit comprises:
a fifth transistor, having a control terminal coupled to the first connection terminal of the third transistor, a first connection terminal, and a second connection terminal coupled to one of the first reference voltage and the second reference voltage; and
a sixth transistor, having a control terminal, a first connection terminal coupled to the read bit line, and a second connection terminal coupled to the first connection terminal of the fifth transistor.

11. The SRAM bit-cell of claim 7, wherein the read buffer circuit is a complementary metal-oxide-semiconductor (CMOS) circuit.

12. The SRAM bit-cell of claim 7, wherein the read buffer circuit is a pass gate.

13. The SRAM bit-cell of claim 7, wherein the read buffer circuit is a combinational logic.

14. The SRAM bit-cell of claim 1, wherein the first reference voltage is lower than the second reference voltage.

15. The SRAM bit-cell of claim 1, wherein the first reference voltage is higher than the second reference voltage.

16. The SRAM bit-cell of claim 1, wherein the SRAM bit-cell located at a selected row and an unselected column, and the cross-coupled latch circuit operates to keep its stored bit unchanged.

17. The SRAM bit-cell of claim 1, wherein the SRAM bit-cell is located at an unselected row and a selected column, and the cross-coupled latch circuit operates to keep its stored bit unchanged.

18. The SRAM bit-cell of claim 1, wherein the SRAM bit-cell is a bit-write-masked SRAM bit-cell located at a selected column and a selected column, and the cross-coupled latch circuit operates to keep its stored bit unchanged.

19. A 12-transistor (12T) two-port static random access memory (SRAM) bit-cell comprising:
a first transistor, having a control terminal, a first connection terminal, and a second connection terminal;
a second transistor, having a control terminal coupled to the control terminal of the first transistor, a first connection coupled to the first terminal of the first transistor, and a second terminal coupled to a first reference voltage;
a third transistor, having a control terminal coupled to the first terminal of the first transistor, a first connection terminal coupled to the control terminal of the first transistor, and a second connection terminal;
a fourth transistor, having a control terminal coupled to the control terminal of the third transistor, a first connection terminal coupled to the first connection terminal of the third transistor, and a second connection terminal coupled to the first reference voltage;
a fifth transistor, having a control terminal coupled to a first write bit line of a write bit line pair, a first connection terminal coupled to the second connection terminal of the first transistor, and a second connection terminal coupled to a second reference voltage;
a sixth transistor, having a control terminal coupled to the first write bit line, a first connection terminal coupled to the first connection terminal of the first transistor, and a second connection terminal;
a seventh transistor, having a control terminal coupled to a second write bit line of the write bit line pair, a first connection terminal coupled to the second connection terminal of the third transistor, and a second connection terminal coupled to the second reference voltage;
an eighth transistor, having a control terminal coupled to the second write bit line, a first connection terminal coupled to the first connection terminal of the third transistor, and a second connection terminal;
a ninth transistor, having a control terminal coupled to a write word line, and two connection terminals coupled to the second connection terminal of the first transistor and the second connection terminal of the third transistor, respectively;
a tenth transistor, having a control terminal coupled to the write word line, a first connection terminal coupled to the second connection terminal of the sixth transistor and the second connection terminal of the eighth transistor, and a second connection terminal coupled to the first reference voltage;
an eleventh transistor, having a control terminal coupled to the first connection terminal of the third transistor, a first connection terminal, and a second connection terminal coupled to one of the first reference voltage and the second reference voltage; and
a twelfth transistor, having a control terminal coupled to a read word line, a first connection terminal coupled to a read bit line, and a second connection terminal coupled to the first connection terminal of the eleventh transistor.

20. The 12T two-port SRAM bit-cell of claim 19, wherein a layout of the 12T SRAM bit-cell defines that:
the seventh transistor, the ninth transistor, the first transistor, a first dummy transistor, a second dummy transistor, the third transistor, a third dummy transistor, and the fifth transistor are at a first row;
a fourth dummy transistor, the tenth transistor, the second transistor, the sixth transistor, the eighth transistor, the fourth transistor, the eleventh transistor, and the twelfth transistor are at a second row adjacent to the first row;
the seventh transistor and the fourth dummy transistor are at a first column;
the ninth transistor and the tenth transistor are at a second column between the first column and a third column;
the first transistor and the second transistor are at the third column between the second column and a fourth column;
the first dummy transistor and the sixth transistor are at the fourth column between the third column and a fifth column;
the second dummy transistor and the eighth transistor are at the fifth column between the fourth column and a sixth column;
the third transistor and the fourth transistor are at the sixth column between the fifth column and a seventh column;
the third dummy transistor and the eleventh transistor are at the seventh column between the sixth column and an eighth column; and
the fifth transistor and the twelfth transistor are at the eighth column.
